(19) United States
(12) Patent Application Publication
(10) Pub. No.: US 2026/0114252 A1
(43) Pub. Date: Apr. 23, 2026

(54) SELF-ALIGNED MULTI-PATTERNING PROCESS

(71) Applicant: International Business Machines Corporation, Armonk, NY (US)

(72) Inventors: Nargess Arabchi, Slingerlands, NY (US); Chanro Park, Clifton Park, NY (US); Yann Mignot, Slingerlands, NY (US); Lawrence Alfred Clevenger, Saratoga Springs, NY (US)

(21) Appl. No.: 18/921,437

(22) Filed: Oct. 21, 2024

(51) Int. Cl. H01L 21/768; H01L 21/033; H01L 21/311; H01L 21/3213

(52) U.S. Cl. CPC H10W 20/069; H10P 76/405; H10P 76/4085; H10P 50/71; H10P 50/73; H10P 76/4088

(57) ABSTRACT

A modified self-aligned litho-etch-litho-etch (SALELE) process is provided that produces a structure such as, for example, a metal line containing structure, in which notching at a cut location of the structure is substantially reduced, and in which the line edge roughness (LER) and linearity of the structure is improved.

### BACKGROUND

The present application relates to semiconductor technology, and more particularly to a self-aligned multi-patterning process (i.e., a modified self-aligned litho-etch-litho-etch (SALELE) process) which improves the line edge roughness (LER) and linearity of a structure that is formed by such a patterning process. The self-aligned multi-patterning process also substantially reduces notching at a cut location within the structure.

Multiple patterning (or multi-patterning) is a class of technologies for manufacturing integrated circuits (ICs), developed for photolithography to enhance the feature density. Multi-patterning is expected to be necessary for the 7 nm node semiconductor processes and beyond. The premise is that a single lithographic exposure may not be enough to provide sufficient resolution. Hence additional exposures would be needed, or else positioning patterns using etched feature sidewalls (using spacers) would be necessary.

Self-aligned multi-patterning processes such as, for example, self-aligned double patterning (SADP), self-aligned quadruple-patterning (SAQP) and SALELE patterning have become a necessity at the most advanced nodes, where traditional litho-etch multi-patterning processes begin to experience alignment control issues, regardless of the lithography technology used. SALELE process combines the two main multiple patterning approaches: (a) Self-Aligned multiple patterning and (b) Litho-Etch/Litho-Etch multi-patterning along with extreme ultra-violet (EUV) technology. This combination creates a patterning methodology that overcomes EUV direct printing limitations and potentially creates a path towards scaling down.

### SUMMARY

A self-aligned multi-patterning process is provided that produces a structure such as, for example, a metal line containing structure, in which notching at a cut location of the structure is substantially reduced, and in which the line edge roughness (LER) and linearity of the structure is improved.

In one aspect of the present application, a self-aligned multi-patterning process is provided. In one embodiment, the self-aligned multi-patterning process includes providing a mandrel line having a first sidewall and a second sidewall that is opposite the first sidewall. The mandrel line is then partially divided by removing an inner portion of the mandrel line to provide a mandrel cut region in the mandrel line, while retaining the first sidewall and the second sidewall adjacent to the mandrel cut region. Next, a dielectric spacer is formed along an entirety of the first sidewall and the second sidewall of the mandrel line.

In another embodiment of the present application, the self-aligned multi-patterning process includes providing an amorphous silicon-containing mandrel line having a first sidewall and a second sidewall that is opposite the first sidewall, wherein silicon oxide is present on the first sidewall and the second sidewall. The amorphous silicon-containing mandrel line is then partially divided by removing an inner portion of the amorphous silicon-containing mandrel line to provide a mandrel cut region in the amorphous silicon-containing mandrel line, while retaining the first sidewall and the second sidewall adjacent to the mandrel cut region. Next, a dielectric spacer is formed along an entirety of the first sidewall and the second sidewall of the amorphous silicon-containing mandrel line.

In another aspect of the present application, a metal line containing structure is provided. In one embodiment of the present application, the metal line containing structure includes at least one electrically conductive metal line embedded in an interlayer dielectric (ILD) material, wherein the at least one electrically conductive metal line has straight sidewalls throughout an entire length thereof and substantially no notching is present along the sidewalls of the at least one electrically conductive metal line.

### BRIEF DESCRIPTION OF THE DRAWINGS

FIG. 1 is a three dimensional (3D) cross sectional view of an exemplary structure including from bottom to top, a substrate, a hard mask layer, a dielectric layer and a mandrel material layer.

FIG. 2 is a 3D cross sectional view of the exemplary structure of FIG. 1 after patterning the mandrel material layer to provide at least one mandrel line.

FIG. 3 is a 3D cross sectional of the exemplary structure of FIG. 2 after partially dividing the at least one mandrel line by removing an inner portion of the mandrel line to provide a mandrel cut region in the mandrel line, while retaining the first sidewall and the second sidewall adjacent to the mandrel cut region.

FIG. 4A is a top-down view of the exemplary structure in the boxed area, i.e., the mandrel cut region, shown in FIG. 3.

FIG. 4B is a 3D view of a first mandrel line which has been partially divided by removing an inner portion of the first mandrel line to provide a mandrel cut region in the first mandrel line, while retaining the first sidewall and the second sidewall adjacent to the mandrel cut region, in which the first sidewall and the second sidewall are both composed of a dielectric oxide.

FIG. 5 is a 3D cross sectional view of the exemplary structure of FIG. 3 after forming a spacer dielectric layer.

FIG. 6 is a 3D cross sectional view of the exemplary structure of FIG. 5 after performing a spacer etch back of the spacer dielectric layer to provide a dielectric spacer located along an entirety of the first sidewall and the second sidewall.

FIG. 7 is a top-down view of the exemplary structure in the boxed area shown in FIG. 6.

FIG. 8 is a 3D cross sectional view of an exemplary structure that can be formed utilizing the self-aligned multi-patterning process of the present application.

FIG. 9 is a top down view of the exemplary structure shown in FIG. 8.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In conventional SALELE patterning, amorphous silicon mandrel lines are created by reactive ion etching using a patterned organic planarization layer (OPL) as an etch mask. The patterned OPL layer is then removed by ashing. Ashing of the OPL creates a silicon oxide layer along the sidewalls of the amorphous silicon mandrel lines. The amorphous silicon mandrel lines are then etched selective to the silicon oxide and thereafter a wet clean that is not selective to the silicon oxide is used to remove silicon oxide and to cut each of the amorphous silicon mandrel lines. During the subsequent formation of a dielectric spacer, notching in the amorphous silicon mandrel lines occurs at a region (i.e., a cut region) that is present between two cut amorphous silicon mandrel lines. The notching transfers downstream and it results in a final structure in which electrically conductive metal lines formed by the conventional SALELE process have notching, are not straight and have an increased line edge roughness due to the notching. There is thus a need to provide a multi-patterning process which substantially reduces notching of the amorphous silicon mandrel lines and thus provides a structure such as, for example, a metal line containing structure, in which the sidewalls of the structure are straight, the LER and notching are substantially reduced.

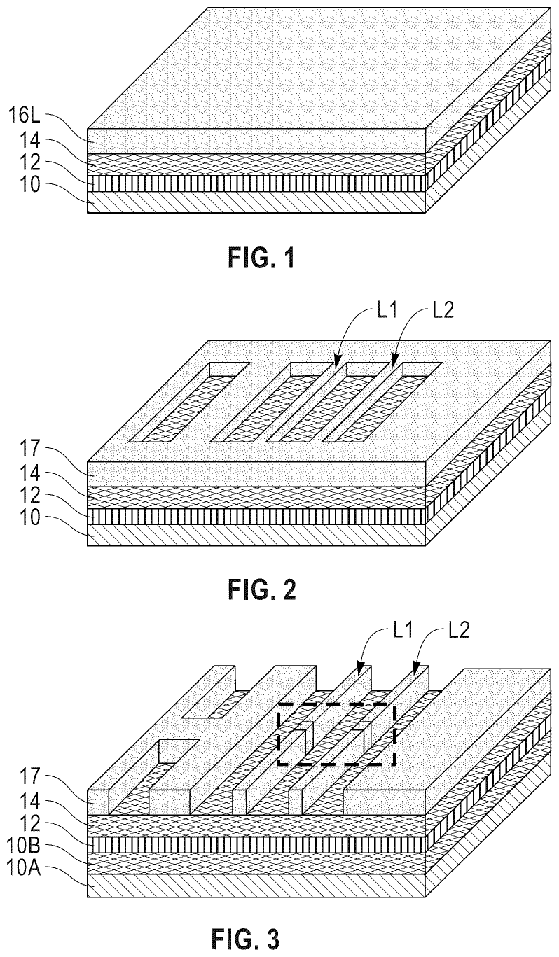

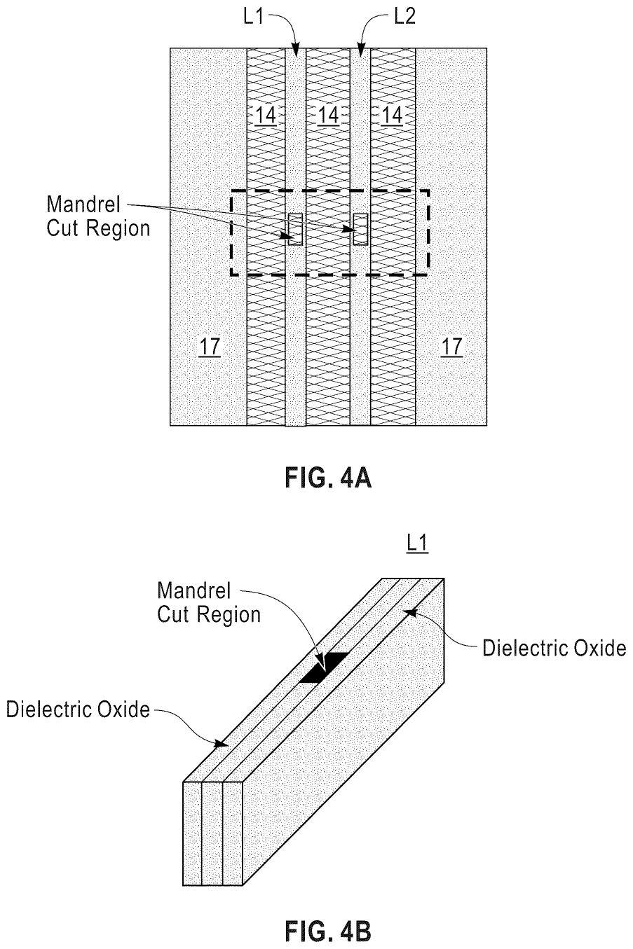

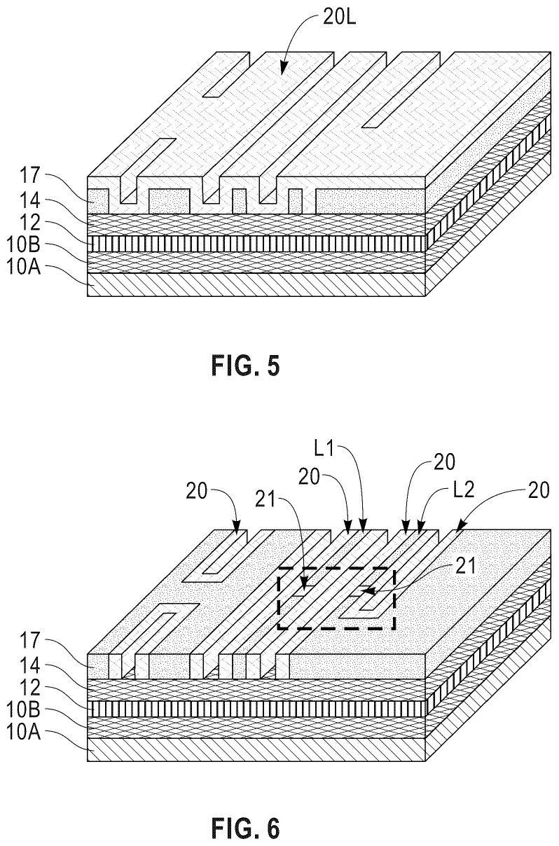

The present application provides a self-aligned multi-patterning process as is exemplified in FIGS. 1-7. Notably, the self-aligned multi-patterning process of the present application is a modified SALELE process that provides a structure in which notching at a cut location of the structure is substantially reduced, and in which the LER and linearity of the structure is improved. Notably, the self-aligned multi-patterning process of the present application includes providing a mandrel line (L1, L2) having a first sidewall and a second sidewall that is opposite the first sidewall; See, for example, FIGS. 1-2. The mandrel line (L1, L2) is then partially divided by removing an inner portion of the mandrel line (L1, L2) to provide a mandrel cut region in the mandrel line, while retaining the first sidewall and the second sidewall adjacent to the mandrel cut region; See, for example, FIGS. 3-4A. Next, a dielectric spacer 20 is formed along an entirety of the first sidewall and the second sidewall of the mandrel line (L1, l2); See, for example, FIGS. 5-7.

The self-aligned multi-patterning process of the present application will now be described in greater detail. Referring first to FIG. 1, there is illustrated an exemplary structure including from bottom to top, a substrate 10, a hard mask layer 12, a dielectric layer 14 and a mandrel material layer 16L that can be employed in accordance with an embodiment of the present application. The exemplary structure shown in FIG. 1 represents one type of structure that can be used in the self-aligned multi-patterning process of the present application. Other types of exemplary structures which include at least substrate 10 and mandrel material layer 16L can be employed in the self-aligned multi-patterning process of the present application.

The substrate 10 can be composed of a dielectric material, an electrically conductive material or a multilayered stack of, and in any order, a dielectric material and an electrically conductive material. When a dielectric material is employed as substrate 10, the dielectric material can include an interlayer dielectric (ILD) material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein are measured in a vacuum unless otherwise noted. Illustrative low-k dielectric materials that can be used as the dielectric material than can be used as substrate 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. The substrate 10 can include a single dielectric material or a multilayered stack of dielectric materials. When the substrate 10 includes a dielectric material, the dielectric material can be formed by a deposition process such as, for example, chemical vapor deposition (CVD), plasma enhanced chemical vapor deposition (PECVD), evaporation or spin-on coating.

When an electrically conductive material is employed as substrate 10, the electrically conductive material can include, for example, an electrically conductive metal, an electrically conductive metal alloy or a multilayered stack including, for example, a first electrically conductive material (i.e., a metal or a metal alloy) and a second electrically conductive material (i.e., metal or metal alloy) that is compositionally different from the first electrically conductive material. Illustrative examples of electrically conductive metals include, but are not limited to, Cu, W, Al, Co, or Ru. An illustrative example of an electrically conductive metal alloy includes Cu—Al alloy. The substrate 10 can include a single electrically conductive material (e.g., metal or metal alloy) or a multilayered stack of electrically conductive materials. When the substrate 10 includes an electrically conductive material, the electrically conductive material can be formed by a deposition process such as, for example, CVD, PECVD, physical vapor deposition (PVD), atomic layer deposition (ALD), plating or sputtering.

The hard mask layer 12 is composed of any hard mask material including but not limited to silicon dioxide, silicon nitride, and/or titanium nitride. The hard mask layer 12 is optional in some embodiments of the present application. The hard mask layer 12 can be a single layered structure, or it can be a multilayered structure including a multilayered stack of hard mask materials. When an uppermost portion of the substrate 10 is composed of a dielectric material, the hard mask material that provides the hard mask layer 12 is compositionally different from the dielectric material that is present in the uppermost portion of the substrate 10. The hard mask layer 12 is formed on top of the substrate 10 utilizing a deposition process such as, for example, CVD, PECVD, PVD, or ALD. In some embodiments, the hard mask layer 12 is formed directly on a topmost surface of the substrate 10. In other embodiments, one or more additional layers can be inserted between the substrate 10 and the hard mask layer 12.

The dielectric layer 14 is composed of any dielectric material such as, for example, the dielectric material mentioned above for substrate 10. The dielectric material that provides the dielectric layer 14 is however compositionally different from the hard mask material that provides the hard mask layer 12. In one example, the dielectric layer 14 is composed of silicon dioxide and the hard mask layer is composed of TiN. The dielectric layer 14 is formed on top of the hard mask layer 12 utilizing a deposition process such as, for example, CVD, PECVD, PVD or ALD. In some embodiments, dielectric layer 14 is formed directly on a topmost surface of the hard mask layer 12. In other embodiments, one or more additional layers (i.e., masking material layers) can be inserted between the dielectric layer 14 and the hard mask layer 12.

The mandrel material layer 16L is a sacrificial material such as, for example, amorphous silicon (a-Si) or amorphous carbon (a-C). In embodiments of the present application, the sacrificial material that provides the mandrel material layer 16L is one in which a dielectric oxide is formed on the sidewalls thereof during a patterning process that is used to pattern the mandrel material layer 16L. The sacrificial material that provides the mandrel material layer 16L is compositionally different from the dielectric layer 14 and the hard mask layer 12. The mandrel material layer 16L can be formed utilizing a deposition process including, but not limited to, CVD, PECVD, PVD, or ALD. In some embodiments, mandrel material layer 16L is formed directly on a topmost surface of the dielectric layer 14 (or directly on a topmost surface of the hard mask layer 12, if the dielectric layer 14 is not present). In other embodiments, one or more additional layers (i.e., masking material layers) can be inserted between the mandrel material layer 16L and the dielectric layer 14 (or directly on a topmost surface of the hard mask layer 12, if the dielectric layer 14 is not present).

Referring now to FIG. 2, there is illustrated the exemplary structure of FIG. 1 after patterning the mandrel material layer 16L to provide at least one mandrel line; in FIG. 2 two mandrel lines, L1, L2L, are denoted by way of one example. Each mandrel line (i.e., L1 and L2) is a component of a patterned mandrel structure 17. The patterning of the mandrel material layer 16L includes first forming (via a deposition process such as, for example, CVD, PECVD, evaporation or spin-on coating) an organic planarization layer (OPL) on the mandrel material layer 16L, and thereafter a lithographic patterning process is performed. Lithographic patterning includes forming a photoresist material (not shown) on a layer/multilayered stack (e.g., the mandrel material layer 16L) that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The OPL and the photoresist material are removed after the pattern transfer process utilizing one or more material removal processes that are selective in removing the OPL and the photoresist material. In the present application, the etch used in the lithographic pattern process is selective in removing physically exposed portions of the mandrel material layer 16L that are not protected by the patterned photoresist material. The pattern transfer etch thus stops on the layer that is located directly beneath the mandrel material layer 16L. In the illustrated embodiment, the etch stops of the dielectric layer 14. In some embodiments and during the etch and subsequent removal of the OPL, a dielectric oxide (not shown) can be formed along the sidewalls of each mandrel line, e.g., L1 and L2, that is formed. In such embodiments, each mandrel line, e.g., L1 and L2, has first and second sidewalls that are composed of a dielectric oxide with the remaining portion of each mandrel line being composed of the original sacrificial material that was used as mandrel material layer 16L. The dielectric oxide that is present along the sidewalls is a thin layer having a thickness of 2 nm or less.

Each mandrel line, e.g., L1 and L2, that is formed has a first sidewall and a second sidewall that is opposite the first sidewall. The first sidewall and a second sidewall of each mandrel line, e.g., L1 and L2, are entirely straight sidewalls. By “straight sidewall” it is meant that an angle, as measured from the sidewall to a topmost surface of a structure (i.e., mandrel lines, L1, l2) and from the same sidewall to the bottom surface of the structure (i.e., mandrel lines, L1, L2), is 90°. Stated in other term, each mandrel line, e.g., L1 and L2, has first and second sidewalls that are perpendicular to a horizontal topmost surface of mandrel line. In some embodiments, the pitch between mandrel lines (between L1 and L2) can be from 20 nm to less than 65 nm. The pitch is measured from one point of one of the mandrel lines (e.g., L1) to the same point on a nearest neighboring mandrel line (e.g., L2).

Each mandrel line, e.g., L1 and L2, has a width, as measured from the first sidewall to the second sidewall that is constant through an entire length of the mandrel line. Note that the width of the various mandrel lines that are formed need not be the same width. At this point of the present application, each mandrel line, e.g., L1 and L2, is a continuous, non-cut structure.

Referring now to FIG. 3, there is illustrated the exemplary structure of FIG. 2 after partially dividing (i.e., cutting) the at least one mandrel line (i.e., L1 and/or L2) by removing an inner portion of the mandrel line (i.e., L1 and/or L2) to provide a mandrel cut region in the mandrel line, while retaining the first sidewall and the second sidewall adjacent to the mandrel cut region. This aspect of the present application is also depicted in FIG. 4A, which is a top-down view of the exemplary structure in the boxed area shown in FIG. 3. The boxed area represents the area in which the mandrel lines (i.e., L1 and/or L2) are partially divided. It is noted that during this step of the present application the mandrel lines (i.e., L1 and/or L2) are released from the patterned mandrel structure 17. In the present application, the first sidewall and the second sidewall that are adjacent to the mandrel cut region provides a fence around the outer perimeter of the mandrel cut region. This “fence’ can be composed of a dielectric oxide such as, for example, silicon oxide. This aspect of the present application is illustrated in FIG. 4B. Notably, FIG. 4B illustrates first mandrel line L1 which has been processed by removing an inner portion of the first mandrel line to provide a mandrel cut region in the first mandrel line, while retaining the first sidewall and the second sidewall adjacent to the mandrel cut region, wherein the first sidewall and the second sidewall are both composed of a dielectric oxide (e.g., silicon oxide). In one example, and when amorphous silicon is used in providing the mandrel material layer 16L (and thus the mandrel lines (L1, L2)) the fence is composed of silicon oxide. This partial dividing includes a lithographic pattern process as described above. In some embodiments, the etch is selective to the dielectric oxide (such as, for example silicon oxide) that is formed on the sidewalls of the mandrel lines and thereafter a wet clean process that is selective to the dielectric oxide (e.g., silicon oxide) can be employed. Contrary to a conventional SALELE process in which the clean is not selective to the dielectric oxide, the clean step of the present application is selective, and thus the dielectric oxide in retained at the mandrel cute region. The inclusion of the ‘fence’ around the outer perimeter of the mandrel cut region is by design and is used in the present application as a means of substantially reducing the notching at the mandrel cut region; notching occurs in the prior art SALELE process since no ‘fence’ is provided around the outer perimeter of the mandrel cut region.

It is noted that in FIG. 3 and FIGS. 5-6, the substrate 10 is depicted as containing a first substrate portion 10A and a second substrate portion 10B. The first substrate portion 10A can include a dielectric material or electrically conductive material as mentioned above for substrate 10, and the second substrate portion 10B can include a dielectric material or electrically conductive material as mentioned above for substrate 10. In one example, the first substrate portion 10A is composed of a first dielectric material, and the second substrate portion 10B is composed of a second dielectric material that is compositionally different from the first dielectric material. In another example, the first substrate portion 10A is composed of a first electrically conductive material, and the second substrate portion 10B is composed of a second electrically conductive material that is compositionally different from the first electrically conductive material.

Referring now to FIG. 5, there is illustrated the exemplary structure of FIG. 3 after forming a spacer dielectric layer 20L. The spacer dielectric layer 20L is composed of a spacer dielectric material including, but not limited to, silicon dioxide, silicon nitride, SiBCN, SiOCN or SiOC. The spacer dielectric layer 20L can be formed by a deposition process such as, for example, CVD or PECVD. The spacer dielectric layer 20L is formed on a topmost surface of each of the mandrel lines (i.e., L1 and L2) and along the first and second sidewalls of each mandrel line. The spacer dielectric layer 20L also pinches off the mandrel cut gap that is created by the mandrel cut region illustrated in FIG. 4. Stated in other terms, spacer dielectric layer 20L (and thus the spacer dielectric material) fills in the mandrel cut region.

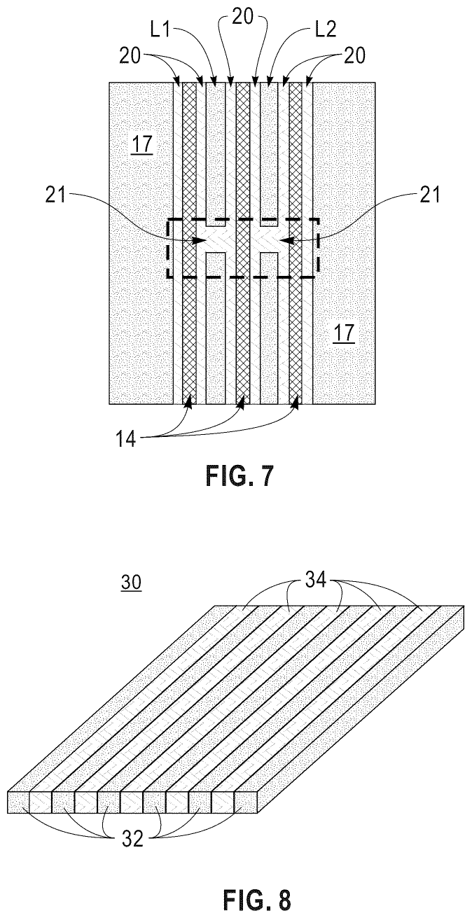

Referring now to FIG. 6 (and FIG. 7), there is illustrated the exemplary structure of FIG. 5 after performing a spacer etch back of the spacer dielectric layer 20L to provide a dielectric spacer 20 located along an entirety of the first sidewall and the second sidewall. It is noted that after the spacer etch back process, spacer dielectric material 21 remains in the mandrel cut region as shown in FIGS. 6-7. Each dielectric spacer 20 that is formed is straight throughout the entire length thereof (even at the pinched off mandrel cut region). Thus, no notching occurs in the dielectric spacers 20 of the present application. Since notching is not present, no notch formation can carry out downstream in the patterning of the substrate 10.

After forming the exemplary structure shown in FIGS. 6 and 7, conventional SALELE processing steps are performed which can include forming a second dielectric spacer along the sidewall of the dielectric spacer 20, removing the mandrel lines and subsequent patterning of the dielectric layer 14, the hard mask layer 12 and thereafter the substrate 10 utilizing the dielectric spacer 20 and the second dielectric spacer as a mandrel pitch doubling spacer etch mask. In some embodiments, the formation of the second dielectric spacer is omitted.

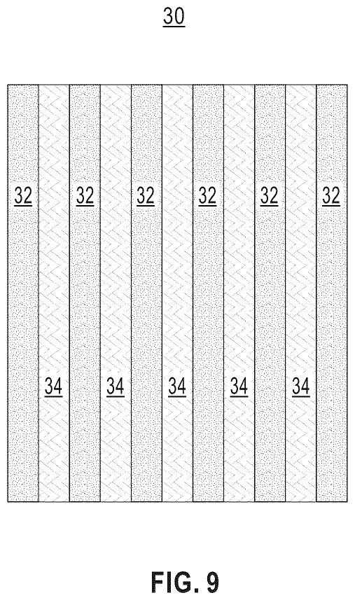

Referring now to FIGS. 8-9, there are illustrated an exemplary structure that can be formed utilizing the self-aligned multi-patterning process of the present application. Notably, the exemplary structure illustrated in FIGS. 8-9 is a metal line containing structure 30 that is composed of an ILD material 32 and electrically conductive metal lines 34. Each electrically conductive metal line 34 has no notching, and has improved (i.e., reduced) LER and linearity. Notably, each electrically conductive metal line 34 is straight along an entire length thereof.

The ILD material 32 includes an ILD material as mentioned previously herein. The electrically conductive metal lines 34 include an electrically conductive material (i.e., a metal or a metal alloy) as mentioned previously herein. In some embodiments, the ILD material 32 represents substrate 10 mentioned above, and then the modified multi-patterning process of the present application is used to pattern metal line openings into the dielectric material containing substrate. The metal line openings are then filled with an electrically conductive metal providing electrically conductive metal lines 34. Filling includes deposition and planarization. In other embodiments, an electrically conductive material is used as the substrate 10, and then the modified multi-patterning process of the present application is used to form metal lines 34 from the substrate 10. The gap that is located between each of the metal lines 34 is thereafter filled with a dielectric material 30. Filling includes deposition and planarization.

Notably, FIGS. 8-9 illustrate a metal line containing structure 30 in accordance with an embodiment of the present application, The metal line containing structure 30 includes at least one electrically conductive metal line 34 embedded in ILD material 32 in which the at least one electrically conductive metal line 34 has straight sidewalls throughout an entire length thereof and substantially no notching is present along the sidewalls of the at least one electrically conductive metal line 34.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A self-aligned multi-patterning process comprising:
providing a mandrel line having a first sidewall and a second sidewall that is opposite the first sidewall;
partially dividing the mandrel line by removing an inner portion of the mandrel line to provide a mandrel cut region in the mandrel line, while retaining the first sidewall and the second sidewall adjacent to the mandrel cut region; and
forming a dielectric spacer along an entirety of the first sidewall and the second sidewall of the mandrel line.

2. The self-aligned multi-patterning process of claim 1, wherein the providing the mandrel line comprises:
forming an organic planarization layer on a mandrel material layer; and
lithographically patterning the mandrel material layer.

3. The self-aligned multi-patterning process of claim 1, wherein the first sidewall and the second sidewall that are adjacent to the mandrel cut region provides a fence around an outer perimeter of the mandrel cut region.

4. The self-aligned multi-patterning process of claim 3, wherein both the first sidewall and the second sidewall are composed of a dielectric oxide.

5. The self-aligned multi-patterning process of claim 4, wherein the partially dividing the mandrel line comprises:
an etch that is selective to the dielectric oxide; and
a wet clean process that is selective to the dielectric oxide.

6. The self-aligned multi-patterning process of claim 1, wherein the mandrel line is composed of amorphous silicon.

7. The self-aligned multi-patterning process of claim 1, wherein the forming the dielectric spacer comprises:
depositing a dielectric spacer layer; and
etching back the dielectric spacer layer.

8. The self-aligned multi-patterning process of claim 7, wherein the dielectric spacer layer pinches off the mandrel cut region, and after etching back the dielectric spacer layer, a portion of the dielectric spacer layer remains in the mandrel cut region.

9. The self-aligned multi-patterning process of claim 1, wherein the mandrel line is positioned over a substrate, the substrate comprising a dielectric material, an electrically conductive metal, or any multilayered stack thereof.

10. The self-aligned multi-patterning process of claim 9, further comprising a hard mask layer and a dielectric layer positioned between the substrate and the mandrel line.

11. A self-aligned multi-patterning process comprising:
providing an amorphous silicon-containing mandrel line having a first sidewall and a second sidewall that is opposite the first sidewall, wherein silicon oxide is present on the first sidewall and the second sidewall;
partially dividing the amorphous silicon-containing mandrel line by removing an inner portion of the amorphous silicon-containing mandrel line to provide a mandrel cut region in the amorphous silicon-containing mandrel line, while retaining the first sidewall and the second sidewall adjacent to the mandrel cut region; and
forming a dielectric spacer along an entirety of the first sidewall and the second sidewall of the amorphous silicon-containing mandrel line.

12. The self-aligned multi-patterning process of claim 11, wherein the providing the amorphous silicon-containing mandrel line comprises:
forming an organic planarization layer on a mandrel material layer; and
lithographically patterning the mandrel material layer.

13. The self-aligned multi-patterning process of claim 11, wherein the first sidewall and the second sidewall that are adjacent to the mandrel cut region provides a fence around an outer perimeter of the mandrel cut region.

14. The self-aligned multi-patterning process of claim 11, wherein the partially dividing of amorphous silicon-containing mandrel line comprises:
an etch that is selective to the silicon oxide; and
a wet clean process that is selective to the silicon oxide.

15. The self-aligned multi-patterning process of claim 11, wherein the forming dielectric spacer comprises:
depositing a dielectric spacer layer; and
etching back the dielectric spacer layer.

16. The self-aligned multi-patterning process of claim 15, wherein the dielectric spacer layer pinches off the mandrel cut region, and after etching back the dielectric spacer layer, a portion of the dielectric spacer layer remains in the mandrel cut region.

17. The self-aligned multi-patterning process of claim 11, wherein the amorphous silicon-containing mandrel line is positioned over a substrate, the substrate comprising a dielectric material, an electrically conductive metal, or any multilayered stack thereof.

18. The self-aligned multi-patterning process of claim 17, further comprising a hard mask layer and a dielectric layer positioned between the substrate and the amorphous silicon-containing mandrel line.

19. A metal line containing structure comprising:
at least one electrically conductive metal line embedded in an interlayer dielectric (ILD) material, wherein the at least one electrically conductive metal line has straight sidewalls throughout an entire length thereof and substantially no notching is present along the sidewalls of the at least one electrically conductive metal line.
